(19) United States
(12) Patent Application Publication
(10) Pub. No.: US 2026/0116060 A1
(43) Pub. Date: Apr. 30, 2026

(54) METHOD FOR MANUFACTURING SEMICONDUCTOR DEVICE USING GAS BLOWING AGENT

(71) Applicant: Samsung Electronics Co., Ltd., Suwon-si (KR)

(72) Inventors: Cheonil PARK, Seongnam-si (KR); MYOUNGCHUL EUM, Asan-si (KR); HWAIL JIN, Seongnam-si (KR)

(21) Appl. No.: 19/420,020

(22) Filed: Dec. 15, 2025

Related U.S. Application Data
(63) Continuation of application No. 17/861,490, filed on Jul. 11, 2022, now Pat. No. 12,521,977.

(30) Foreign Application Priority Data
Sep. 3, 2021 (KR) 10-2021-0117324

(51) Int. Cl. B32B 37/12; B32B 3/30; B32B 7/12; B32B 37/18; B32B 38/10; H10P 52/00; H10P 72/70; H10W 20/00

(52) U.S. Cl. CPC B32B 37/12; B32B 3/30; B32B 7/12; B32B 37/18; B32B 38/10; H10P 52/00; H10P 72/7402; H10W 20/023; B32B 2037/1253; B32B 2255/26; B32B 2305/022; B32B 2305/30; B32B 2310/0831; B32B 2457/14

(57) ABSTRACT

An adhesive member includes a base film having a first surface and a second surface opposite to the first surface, a carrier adhesive film disposed on the first surface of the base film and configured to contact a carrier substrate, and a device adhesive film disposed on the second surface of the base film and configured to contact a device wafer. The device adhesive film includes a gas blowing agent, and the carrier adhesive film does not include any gas blowing agent.

### CROSS-REFERENCE TO RELATED APPLICATIONS

This U.S. non-provisional patent application claims priority under 35 U.S.C. § 119 to Korean Patent Application No. 10-2021-0117324, filed on Sep. 3, 2021, the entire contents of which are hereby incorporated by reference.

### BACKGROUND

The present disclosure herein relates to a method for manufacturing a semiconductor device, and more particularly, to a method for manufacturing a semiconductor device using a gas blowing agent.

With the development of electronics industry, electronic components are required to have higher-level functions, higher speed, and smaller size. To support this trend, the size of a semiconductor chip may be reduced. To this end, a wafer is processed to reduce its thickness through a back grinding process or the like during a semiconductor manufacturing process. However, a crack may occur in a wafer during a semiconductor memory device manufacturing process, thus causing a reduction in yield.

### SUMMARY

The present disclosure provides a method of manufacturing a semiconductor device capable of improving yield.

The purposes of the present disclosure are not limited to the above-mentioned purposes, and other purposes not mentioned will be understood by those skilled in the art from the disclosure below.

An embodiment of the inventive concept provides a method for manufacturing a semiconductor device, including bonding a carrier substrate onto a device wafer with an adhesive member, wherein the adhesive member includes a base film, a device adhesive film disposed on a first (e.g., lower) surface of the base film and contacting the device wafer, and a carrier adhesive film disposed on a second (e.g., upper) surface of the base film and contacting the carrier substrate, wherein the device adhesive film includes a gas blowing agent, and the carrier adhesive film does not include a gas blowing agent.

In an embodiment of the inventive concept, a method of manufacturing a semiconductor device includes: bonding a carrier substrate onto a device wafer with an adhesive member therebetween; a first curing of the adhesive member by radiating first light of a first wavelength through the carrier substrate; reducing a thickness of the device wafer by performing a back grinding process on the device wafer; a second curing of the adhesive member by radiating second light of a second wavelength that is different from the first wavelength through the carrier substrate, and forming pores between the adhesive member and the wafer substrate; and separating the carrier substrate and the adhesive member from the device wafer.

In an embodiment of the inventive concept, a method of manufacturing a semiconductor device includes: bonding a carrier substrate onto a device wafer with an adhesive member; a first curing the adhesive member by radiating first ultraviolet light of a first wavelength through the carrier substrate; reducing a thickness of the device wafer by performing a back grinding process on the device wafer; a second curing the adhesive member by radiating second ultraviolet light of a second wavelength that is different from the first wavelength through the carrier substrate, and forming pores between the adhesive member and the wafer substrate; and separating the carrier substrate and the adhesive member from the device wafer, wherein the adhesive member includes: a base film; a device adhesive film disposed on a lower surface of the base film and contacting the device wafer; and a carrier adhesive film disposed on an upper surface of the base film and contacting the carrier substrate, wherein the device adhesive film includes a gas blowing agent, and the carrier adhesive film does not include a gas blowing agent.

### BRIEF DESCRIPTION OF THE FIGURES

The accompanying drawings are included to provide a further understanding of the inventive concept. In the drawings:

FIG. 1 is a flowchart illustrating a method of manufacturing a semiconductor device according to embodiments of the inventive concept;

FIGS. 2A to 2H are cross-sectional views illustrating a sequence of steps for manufacturing a semiconductor device according to embodiments of the inventive concept;

FIG. 3A is an enlarged view of the portion P1 of FIG. 2A according to embodiments of the inventive concept;

FIG. 3B is an enlarged view of the portion P2 of FIG. 2B according to embodiments of the inventive concept;

FIG. 3C is an enlarged view of the portion P1 of FIG. 2C according to embodiments of the inventive concept;

FIG. 3D is an enlarged view of the portion P1 of FIG. 2D according to embodiments of the inventive concept;

FIG. 3E is an enlarged view of the portion P2 of FIG. 2E according to embodiments of the inventive concept;

FIG. 4 is a cross-sectional view illustrating a method for manufacturing a semiconductor device according to embodiments of the inventive concept;

FIG. 5 is a cross-sectional view illustrating a method for manufacturing a semiconductor device according to embodiments of the inventive concept;

FIG. 6 is a cross-sectional view illustrating a method for manufacturing a semiconductor device according to embodiments of the inventive concept; and

FIG. 7 is an enlarged view of the portion P2 of FIG. 2B according to embodiments of the inventive concept.

### DETAILED DESCRIPTION

Hereinafter, embodiments according to the inventive concept will be described in detail with reference to the drawings.

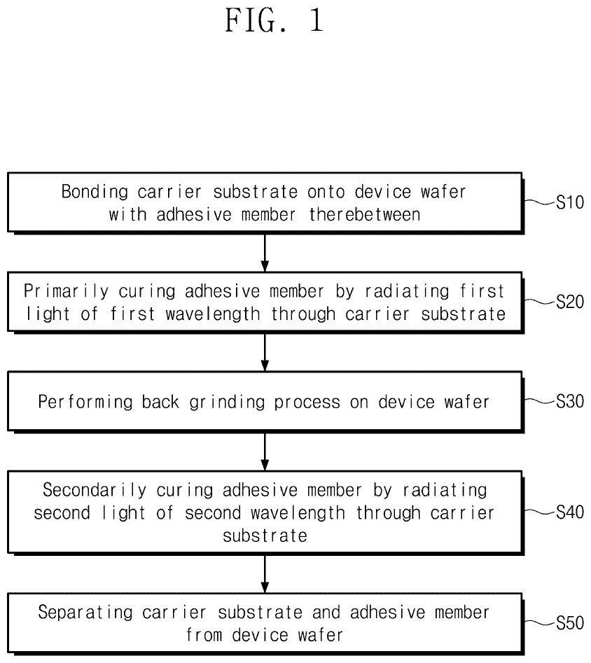

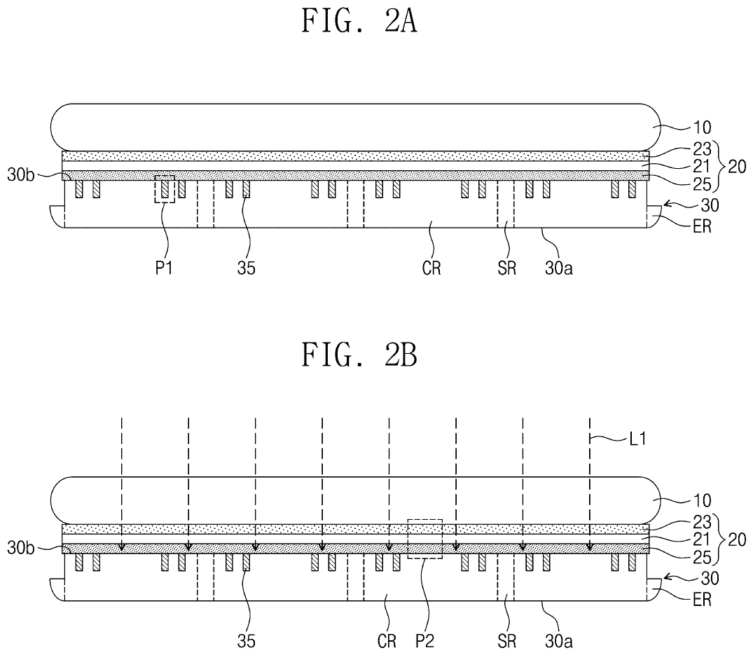

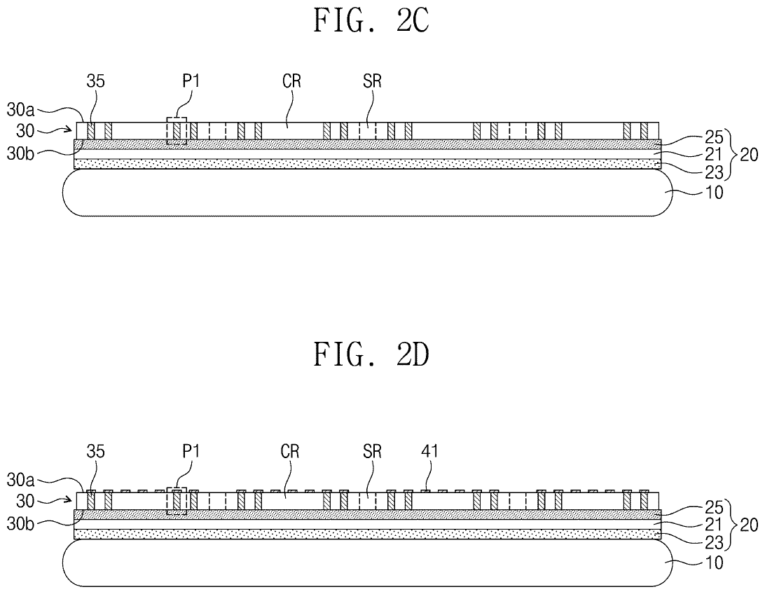

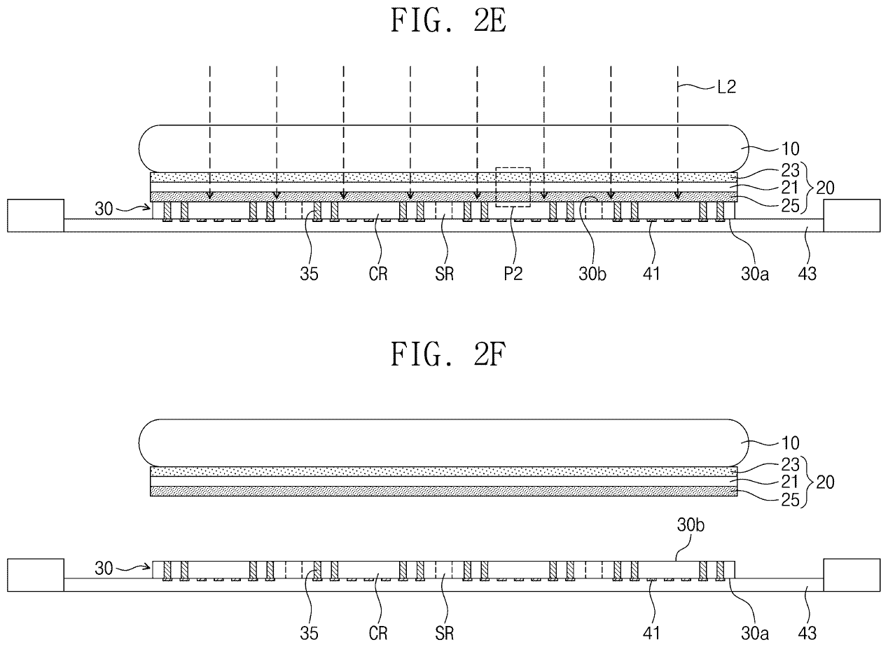

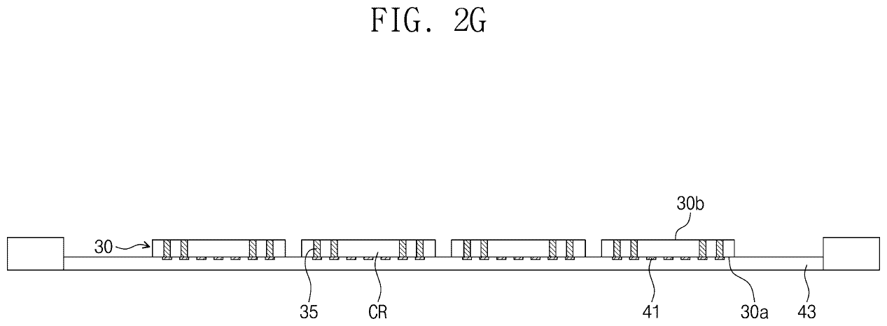

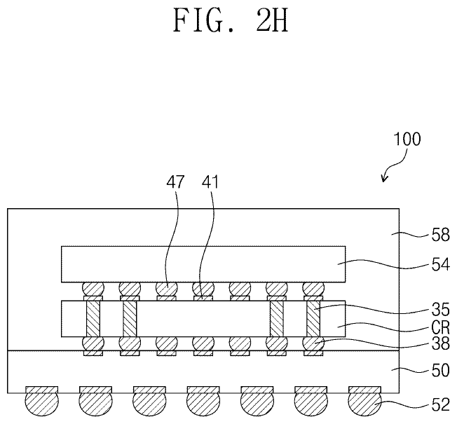

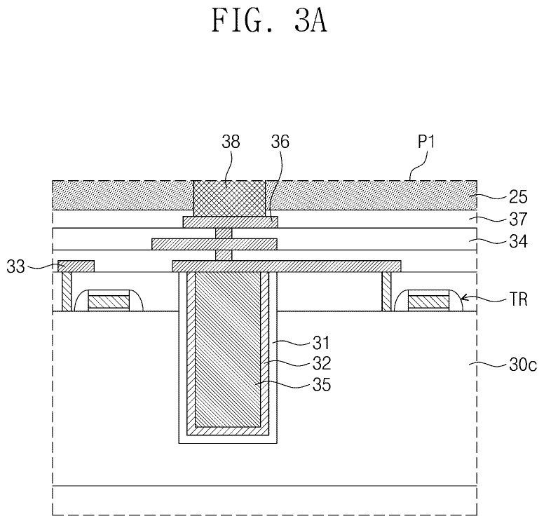

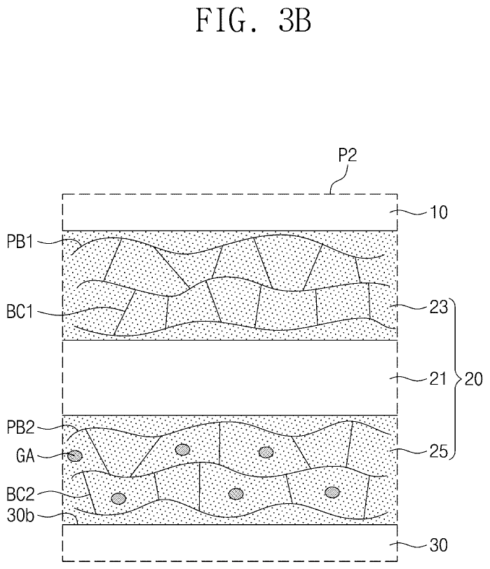

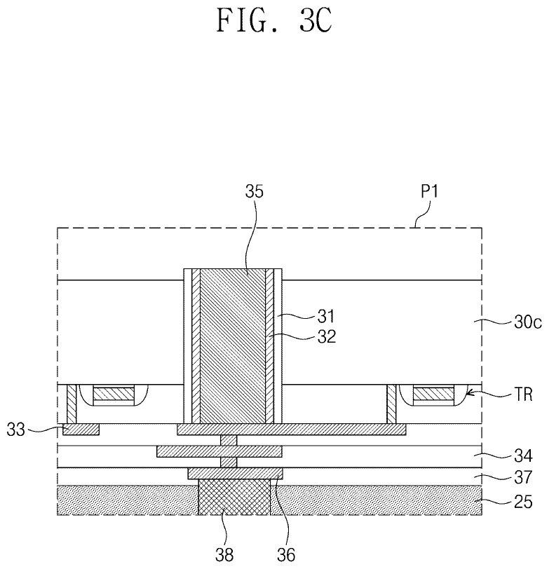

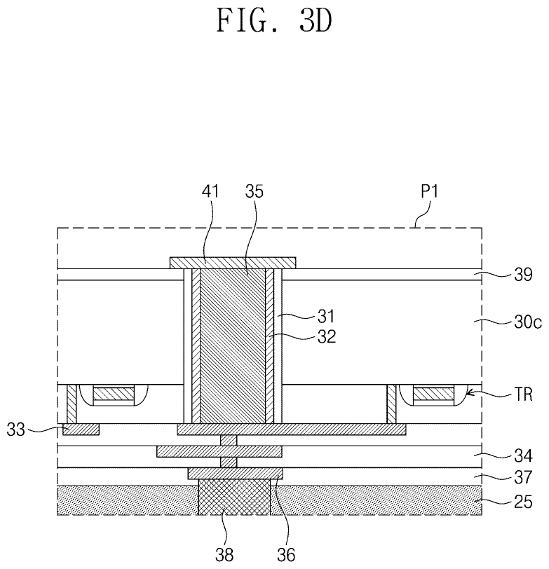

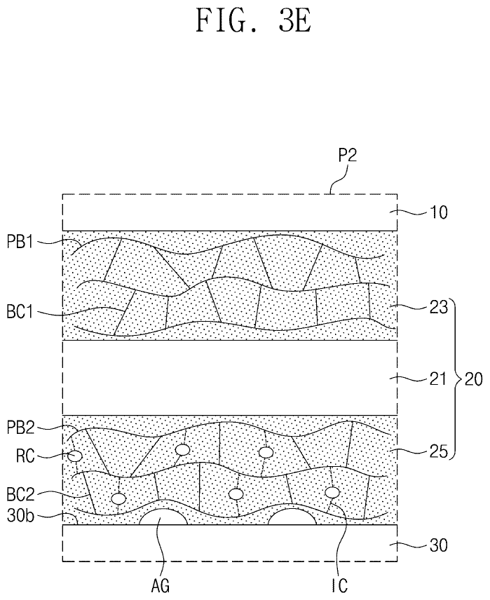

FIG. 1 is a flowchart illustrating a method for manufacturing a semiconductor device according to embodiments of the inventive concept. FIGS. 2A to 2H are cross-sectional views sequentially illustrating a method for manufacturing a semiconductor device according to embodiments of the inventive concept. FIG. 3A is an enlarged view of the portion P1 of FIG. 2A according to embodiments of the inventive concept. FIG. 3B is an enlarged view of the portion P2 of FIG. 2B according to embodiments of the inventive concept. FIG. 3C is an enlarged view of the portion P1 of FIG. 2C according to embodiments of the inventive concept. FIG. 3D is an enlarged view of the portion P1 of FIG. 2D according to embodiments of the inventive concept. FIG. 3E is an enlarged view of the portion P2 of FIG. 2E according to embodiments of the inventive concept.

Referring to FIGS. 1 and 2A, a carrier substrate 10, a device wafer 30, and an adhesive member 20 are prepared. The carrier substrate 10 is bonded to the device wafer 30 with the adhesive member 20 (formed therebetween) (first operation, S10).

The carrier substrate 10 may be transparent. For example, the carrier substrate 10 may be formed of glass and allow transmission of light (e.g., ultraviolet light) that may cause a chemical reaction in or otherwise change the characteristics of the adhesive member 20.

The device wafer 30 may have various semiconductor devices are formed therein. The device wafer 30 includes a first surface 30a and a second surface 30b facing away from each other. The first surface 30a may be a backside surface of the device wafer 30 and the second surface 30b may be an active surface of the device wafer 30 (corresponding to active surfaces of the semiconductor devices formed therein). The device wafer 30 includes a plurality of chip regions CR, scribe regions SR therebetween, and a edge region ER at the edge of the device wafer 30. The scribe regions SR may be formed as scribe lanes running in two perpendicular directions (from a top down perspective) to define a grid with chip regions CR forming grid elements of the grid. The edge region ER may form a bezel and may have a height difference with upper portions of the chip regions CR. Each chip region CR may form a semiconductor device that when cut form the device wafer 30 forms a corresponding semiconductor chip.

Referring to FIG. 3A, in detail, the device wafer 30 includes transistors TR formed on and/or in a wafer substrate 30c in the chip regions CR. The wafer substrate 30c may be a crystalline semiconductor (e.g., crystalline Si, Si/Ge, Ge, etc.) and may be selectively doped with charge carrier dopants. The exposed surface of the wafer substrate 30c (lower surface in FIGS. 2A, 2B and 3A) may form the device wafer 30 first surface 30a (e.g., a backside surface of the device wafer 30). Portions of the wafer substrate 30c may form substrates of the semiconductor devices formed in the chip regions CR. FIG. 3A illustrates a transistor TR having a gate (hashed portion) formed on wafer substrate 30c, with a gate dielectric separating the gate from the wafer substrate 30c. As is conventional, the transistor TR may include a channel region (not shown) formed in the substrate 30c and have source/drain regions (not shown) formed on opposite sides of the channel region. The transistors TR are covered with interlayer dielectrics 34 (ILDs). Wirings 33 are arranged between the interlayer dielectrics 34. Each interlayer dielectric 34 may be formed as a single layer or multilayer structure of at least one of SiN, SiO₂, SION, SiOC, tetraethyl orthosilicate (TEOS), high density plasma (HDP) oxide, undoped silicate glass (USG), SiCN, or porous insulating material. The wirings 33 may be formed of a single layer or multiple layers of metal such as tungsten, aluminum, copper, titanium, tantalum, ruthenium, and/or iridium. Each layer of wirings 33 may comprise a plurality of separately formed wirings 33 that are interconnected to other corresponding wirings 33 of other layer of wirings 33 to interconnect various transistors TR to each other (to form logic devices and interconnections between logic devices to form an integrated circuit of the corresponding semiconductor device) as well as to interconnect external terminals of the semiconductor device to the integrated circuit (e.g., to provide power and communicate signals between the semiconductor device and an external device).

FIG. 3C illustrates structure for forming a through substrate via (TSV) 35 penetrates a portion of the wafer substrate 30c and a lowermost interlayer dielectric 34 among the interlayer dielectrics 34. Upon further processing (e.g., as shown in FIG. 3C and described below), the through substrate vias 35 fully penetrate the wafer substrate 30c (e.g., after thinning the wafer substrate 30c). The through substrate via 35 may contact a lowermost wiring 33 among the wirings 33. The through substrate via 35 may be formed of metal such as copper and tungsten. A diffusion barrier film 32 and a via insulating film 31 may be conformally arranged between the through substrate via 35 and the wafer substrate 30c and between the through substrate via 35 and the interlayer dielectric 34. The diffusion barrier film 32 and the via insulating film 31 may cover a lower surface of the through substrate via 35. The via insulating film 31 may be spaced apart from a lower surface of the wafer substrate 30c. The diffusion barrier film 32 may include, for example, at least one of titanium, tantalum, titanium nitride, tantalum nitride, or tungsten nitride. The via insulating film 31 may include, for example, a silicon oxide. Alternative structures and processes for forming the through substrate vias 35 are also applicable, such as through substrate vias 35 that fully penetrate the entire semiconductor device (to extend to second surface 30b). When the wafer substrate 30c is formed of silicon, the through substrate vias 35 may be referred to as through silicon vias 35.

A first conductive pad 36 is disposed on an uppermost interlayer dielectric 34. First conductive pads 36 may be chip pads formed at the outermost surface of the device wafer 30 and form external terminals of the semiconductor devices. The uppermost interlayer dielectric 34 and a portion of the first conductive pad 36 are covered with a first passivation film 37. The first passivation film 37 may form an outermost layer of the semiconductor devices and form second surface 30b. The first passivation film 37 may initially cover the first conductive pads 36, and then patterned to form corresponding holes in the first passivation film 37 that expose corresponding first conductive pads 36 for connecting the semiconductor devices to external devices. For example, FIG. 3A illustrates a first conductive bump 38 which may be disposed on and contact the first conductive pad 36 through a hole in the first passivation film. The first conductive bump 38 may be formed of tin, lead, copper, or the like. The first conductive bump 38 may include at least one of a copper bump, copper pillar, or solder ball. The first conductive bump 38 may protrude above the first passivation film 37 so that the second surface 30b may have a protrusion-and-recess structure. Alternatively, an upper surface of the first conductive bump 38 may be coplanar with an upper surface of the first passivation film 37, and the second surface 30b may be even. Alternatively, the conductive bump 38 may be added at a later time, such as after separating the semiconductor devices (e.g., singulating the wafer).

Although FIG. 3A illustrates the through substrate via 35 as contacting the lowermost wiring 33, the through substrate via 35 may contact the wiring 33 of another layer, may have an upper surface having the same height as an upper surface of the wafer substrate 30c, or fully extend through the device wafer 30 and terminate at the second surface 30b.

Referring back to FIG. 2A, the adhesive member 20 is a multi-layered film and may include a base film 21, a carrier adhesive film 23 contacting an upper surface of the base film 21 and contacting the carrier substrate 10, and a device adhesive film 25 contacting a lower surface of the base film 21 and contacting the device wafer 30. The adhesive member 20, for example, may be a double sided tape. That is, the adhesive member 20 may be provided in a form in which two sides of the base film 21 are respectively coated with the carrier adhesive film 23 and the device adhesive film 25. The carrier adhesive film 23 may have a thickness of about 10 nm to about 500 μm. The base film 21 may have a thickness of about 10 nm to about 500 μm. The device adhesive film 25 may have a thickness of about 10 nm to about 500 μm.

The base film 21 may serve to support the carrier adhesive film 23 and the device adhesive film 25. The base film 21 may absorb light of a wavelength of about 300 nm or less.

Since the base film 21 is provided, the adhesive member 20 may be easily handled, and a wafer support system (WSS) process may be performed with ease. The base film 21, for example, may be transparent to allow ultraviolet light to be transmitted therethrough. The base film 21 may be insensitive to may not react with light within a certain wavelength, such as being insensitive to ultraviolet light. The base film 21, for example, may be a polymer film such as polypropylene (PP), polyethylene (PE), polyvinyl chloride (PVC), polyethylene terephthalate (PET), and polyimide (PI).

The carrier adhesive film 23 may include a first resin, a first cross-linking agent, a first filler, and a first release agent so as to have appropriate bonding force on a surface of the carrier substrate 10. The device adhesive film 25 may include a second resin, a second cross-linking agent, a second filler, and a second release agent so as to have appropriate bonding force to a surface of the device wafer 30. The first resin and the second resin may be the same or different from each other. The first resin and the second resin, for example, may be an acrylate-based polymer. The first resin and the second resin, for example, may have a structure of Chemical Formula 1 below.

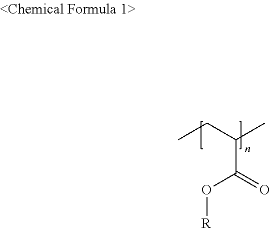

In Chemical Formula 1, n denotes an arbitrary natural number, and R may denote one of hydrogen, alkyl group, alkenyl group, and alkanyl group.

The first cross-linking agent and the second cross-linking agent may be the same or different from each other. The first cross-linking agent and the second cross-linking agent, for example, may be cyanate-based. The first cross-linking agent and the second cross-linking agent, for example, may individually have one of structure I and structure II of Chemical Formula 2 below.

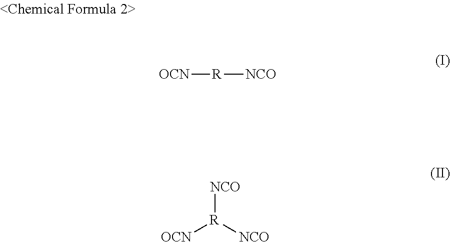

In Chemical Formula 2, R may denote one of hydrogen, alkyl group, alkenyl group, and alkanyl group. Bonding force of the carrier adhesive film 23 and the device adhesive film 25 may be adjusted according to content of the first cross-linking agent and the second cross-linking agent.

The first filler and the second filler may be the same or different from each other. The first filler and the second filler, for example, may be silica, alumina, ceria, or titania. The first filler and the second filler may be added to adjust mechanical strength or modulus of the carrier adhesive film 23 and the device adhesive film 25.

The first release agent and the second release agent may be the same or different from each other. The first release agent and the second release agent, for example, may be silicone acrylate. The first release agent and the second release agent, for example, may have a structure of Chemical Formula 3 below.

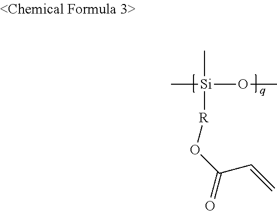

In Chemical Formula 3, q denotes an arbitrary natural number, and R may denote one of alkyl group, alkenyl group, and alkanyl group. In Chemical Formula 3, a silicon-bonded part is hydrophobic, and thus may deteriorate adhesive strength. The first release agent and the second release agent may be added to adjust adhesive strength of the carrier adhesive film 23 and the device adhesive film 25.

The device adhesive film 25 may further include a gas blowing agent. On the contrary, the carrier adhesive film 23 may not include the gas blowing agent. The gas blowing agent may be a material (or photoinitiator), which is decomposed by light of a specific wavelength causing formation of a gas, such as formation of nitrogen gas. A highly reactive radical may also be formed during such decomposition.

The gas blowing agent may be diazirine. As shown in Chemical Reaction Formula 1 below, the diazirine, for example, may be decomposed by ultraviolet light of a wavelength W2 of about 350 nm to about 400 nm, more specifically, about 355 nm, thus forming nitrogen (N₂) gas and a carbene radical.

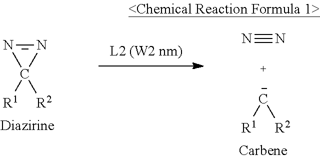

In Chemical Reaction Formula 1, R1 and R2 of the diazirine may individually denote one of hydrogen, alkyl group, alkenyl group, and alkanyl group.

The carrier adhesive film 23 may include the first resin in an amount of about 80-99 wt % based on a total weight of the carrier adhesive film 23. The carrier adhesive film 23 may include the first cross-linking agent in an amount of about 0.001-1 wt % based on the total weight of the carrier adhesive film 23. The carrier adhesive film 23 may include the first filler in an amount of about 0.001-1 wt % based on the total weight of the carrier adhesive film 23. The carrier adhesive film 23 may include the first release agent in an amount of about 0.001-1 wt % based on the total weight of the carrier adhesive film 23.

The device adhesive film 25 may include the second resin in an amount of about 80-99 wt % based on a total weight of the device adhesive film 25. The device adhesive film 25 may include the second cross-linking agent in an amount of about 0.001-1 wt % based on the total weight of the device adhesive film 25. The device adhesive film 25 may include the second filler in an amount of about 0.001-1 wt % based on the total weight of the device adhesive film 25. The device adhesive film 25 may include the second release agent in an amount of about 0.001-1 wt % based on the total weight of the device adhesive film 25. The device adhesive film 25 may include the gas blowing agent in an amount of about 0.001-1 wt % based on the total weight of the device adhesive film 25.

Referring to FIGS. 1, 2B, and 3B, the adhesive member 20 is primarily cured by being irradiated with first light L1 of a first wavelength W1 through the carrier substrate 10 (second operation, S20). Adhesive strength of the adhesive member 20 between the carrier substrate 10 and the device wafer 30 may be reinforced due to the primary curing.

In detail, the first light L1 of the first wavelength W1 is radiated to the adhesive member 20 through the carrier substrate 10 in a state in which the carrier substrate 10 and the device wafer 30 are bonded to each other with the adhesive member 20 therebetween. The gas blowing agent may be substantially insensitive to the light of the first wavelength W1 so that it does not decompose and form gas upon exposure to light of the first wavelength. The first wavelength W1 may be about 300 nm to about 349 nm, and the first light L1 may be ultraviolet light. Accordingly, in the carrier adhesive film 23 and the device adhesive film 25 of the adhesive member 20, a primary curing reaction may occur, in which the first light L1 causes the first cross-linking agent and the second cross-linking agent to cross link the first resin and the second resin. In detail, due to the primary curing reaction, first polymer chains PB1 of the first resin may be connected by first cross-linking groups BC1 of the first cross-linking agent in the carrier adhesive film 23. Furthermore, due to the primary curing reaction, second polymer chains PB2 of the second resin may be connected by second cross-linking groups BC2 of the second cross-linking agent in the device adhesive film 25. Particles of the gas blowing agent GA may be dispersed between the second polymer chains PB2 and the second cross-linking groups BC2 in the device adhesive film 25. Due to the primary curing reaction, modulus of the carrier adhesive film 23 and the device adhesive film 25 of the adhesive member 20 may increase, and the adhesive member 20 may securely fix the device wafer 30 to the carrier substrate 10.

Referring to FIGS. 1, 2B, 2C, 3A, and 3C, a back grinding process is performed on the device wafer 30 (third operation, S30). In detail, the back grinding process is performed in an overturned state in which the first surface 30a of the device wafer 30 faces upwards (as shown in FIGS. 2C and 2D) so as to remove a portion of the wafer substrate 30c adjacent to the first surface 30a of the device wafer 30 (e.g., removal of a predetermined thickness of the wafer substrate 30c). Accordingly, a portion of the wafer substrate 30c, a portion of the via insulating film 31, and a portion of the diffusion barrier film 32 may be removed, and the through substrate via 35 may be exposed. Here, the bezel part of edge region ER may also be removed. A sidewall of the insulating film 31 may be partially exposed by etching back a portion of the wafer substrate 30c. The first surface 30a of the of the device wafer 30 may change its configuration during the manufacturing process, such as after the back grinding process.

Referring to FIGS. 2D and 3D, a second passivation film 39 is formed on a back side of the wafer substrate 30c. Furthermore, a second conductive pad 41 is formed in contact with the through substrate via 35. Although not illustrated, a process of forming a bump or rewiring contacting the second conductive pad 41 may be performed as a follow-up process.

The device wafer 30 is separated from the carrier substrate 10 when an additional process is not required after performing a pad forming process and back grinding process on the first surface 30a of the device wafer 30. This will be described in detail with reference to FIGS. 1, 2E, and 2F.

Referring to FIG. 2E, the device wafer 30 to which the carrier substrate 10 is attached is placed on, for example, a chip bonding tape 43. Here, the first surface 30a of the device wafer 30 is brought into contact with the chip bonding tape 43.

Referring to FIGS. 1 and 2E, the adhesive member 20 is secondarily cured by being irradiated with second light L2 of a second wavelength W2 through the carrier substrate 10 (fourth operation, S40). Adhesive strength between the device wafer 30 and the adhesive member 20 may decrease due to the irradiation of the second light L2 radiated during secondary curing.

In detail, the second light L2 of the second wavelength W2 is radiated to the adhesive member 20 through the carrier substrate 10. The second wavelength W2 may be different from the first wavelength W1 of the first light L1 of FIG. 2B. For example, the second wavelength W2 may be greater than the first wavelength W1, such as the second wavelength W2 being about 350 nm to about 400 nm. The second light L2 may be ultraviolet light.

Referring to FIGS. 2E, 3B, and 3E, the gas blowing agent GA included in the device adhesive film 25 may be decomposed, thus forming nitrogen (N₂) gas and radicals RC. The radicals RC further cross link the second polymer chains PB2 in the device adhesive film 25 so that internal bonds IC are formed between the second polymer chains and the radicals RC and so that the second polymer chains PB2 are further bonded to each other though the radicals RC (e.g., increasing the cross-linking of the second polymer chains PB2). Accordingly, a secondary curing process progresses in the device adhesive film 25, and this may be expressed by Chemical Reaction Formula 2.

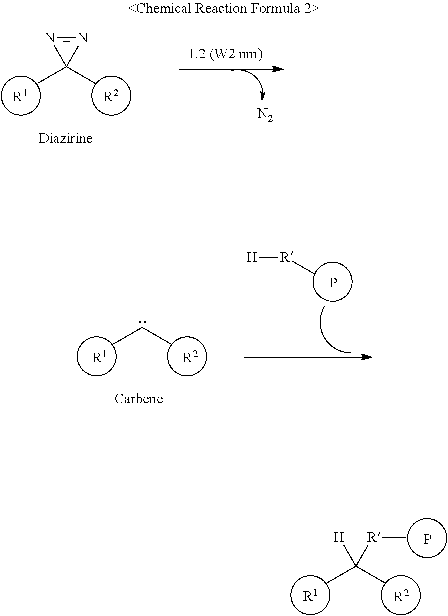

In Chemical Reaction Formula 2, diazirine that is the gas blowing agent may be decomposed to nitrogen (N₂) gas and carbene that is a radical as shown in Chemical Reaction Formulas 1 and 2.

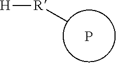

of Chemical Reaction Formula 2 may correspond to the second resin included in the device adhesive film 25. In

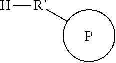

of Chemical Reaction Formula 2, P may denote a functional group, and R′ may denote alkyl group, alkenyl group, or alkanyl group. The functional group may be a hydroxyl group, carboxyl group, or the like. The carbene is bonded to the second polymer chains PB2 of the second resin. That is, the carbene may form a new C—C bond by reacting with carbon and/or hydrogen of the second resin.

Therefore, a cross-linking degree/curing degree of the device adhesive film 25 may further increase, and thus the modulus of the device adhesive film 25 may increase, the adhesive film 25 stays together so that the entire adhesive film 25 is removed with removal of the carrier substrate 10. Furthermore, the nitrogen gas may form pores AG (gaps filled with nitrogen gas, which may also be referred to herein as airgaps) between the device adhesive film 25 and the device wafer 30, and thus the adhesive strength between the device adhesive film 25 and the device wafer 30 may be reduced. As shown in FIG. 3E, the pores AG may be formed along the second surface 30b of the device wafer 30, and thus the pores AG may reduce the surface area of second surface 30b that is in contact with device adhesive film 25. Accordingly, the adhesive strength between the adhesive member 20 and the device wafer 30 may be reduced.

On the contrary, since the carrier adhesive film 23 does not include the gas blowing agent GA, Chemical Reaction Formulas 1 and 2 do not occur in the carrier adhesive film 23. Therefore, the secondary curing process does not occur in the carrier adhesive film 23. Therefore, adhesive strength between the carrier adhesive film 23 and the carrier substrate 10 is not reduced.

Referring to FIGS. 1 and 2F, the adhesive member 20 and the carrier substrate 10 are separated from the device wafer 30 (fifth operation, S50). As described above, since the adhesive strength between the adhesive member 20 and the device wafer 30 has been reduced, the adhesive member 20 and the carrier substrate 10 may be easily separated from the device wafer 30. Accordingly, a crack does not occur in the device wafer 30. Furthermore, the combination of the carrier substrate and the adhesive member may be removed together with this separation step (S50) (the carrier substrate and the adhesive member are attached to each other during and immediately after separating from the device wafer) improving the speed of this peel-off process.

As semiconductor devices are decreased in size, a thickness of the device wafer 30 is decreased, and thus the device wafer 30 may be more vulnerable to a crack. However, a crack or edge chipping of the device wafer 30 or tearing of a passivation film may be minimized/prevented by using a semiconductor device manufacturing method according to the inventive concept. Accordingly, yield may be improved since the device wafer 30 does not break. Furthermore, accordingly, a speed of a separation process or peel-off process may be improved, and thus the yield may be further improved.

Referring to FIG. 2G next, the chip regions CR (and the semiconductor devices formed in the chip regions CR) are separated from each other by cutting the wafer along the scribe regions SR, such as by performing a sawing process or other singulation process, thus forming a plurality of semiconductor chips. In some examples, if not formed previously, the first conductive bumps 38 may be attached to the first conductive pads to the device wafer 30 prior to the chip region CR separation (e.g., to structure corresponding to that shown in FIG. 2F) or after chip region CR separation (e.g., to structure corresponding to that shown in FIG. 2G). Referring to FIG. 2H, the separated chip regions CR are mounted on a package substrate 50 in a flip chip bonding manner, for example. The package substrate 50 may be a printed circuit board or rewiring substrate. The chip region CR may form a first semiconductor chip CR. A second semiconductor chip 54 is mounted on the first semiconductor chip CR in a flip chip bonding manner using an internal solder balls 47. A mold film 58 covering the first semiconductor chip CR and the second semiconductor chip 54 is formed by performing a mold process. Furthermore, a semiconductor package 100 is formed by attaching an external solder ball 52 to a lower portion of the package substrate 50. Although a single first semiconductor chip CR is illustrated in FIG. 2G, several such first semiconductor chips CR may be provided, such as by being stacked between the package substrate 50 and the second semiconductor chip 54.

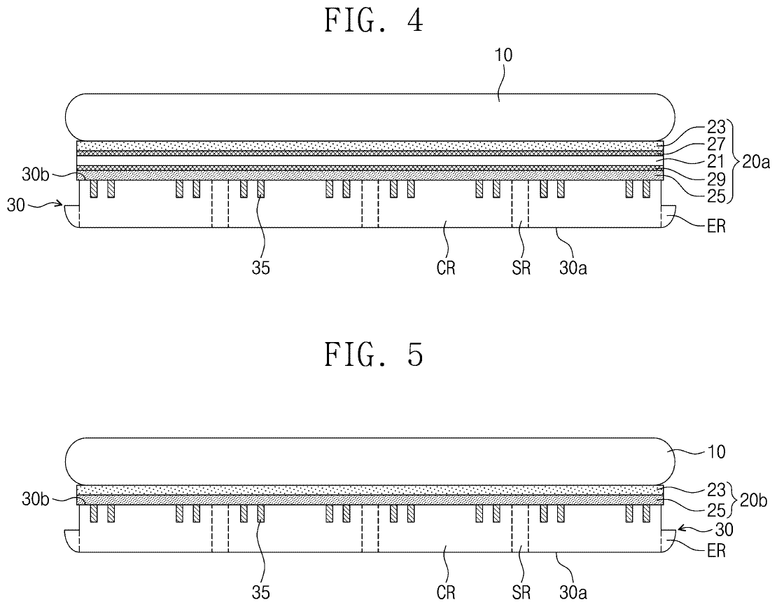

FIG. 4 is a cross-sectional view illustrating a method for manufacturing a semiconductor device according to embodiments of the inventive concept.

Referring to FIG. 4, an adhesive member 20a may further include a first adhesive auxiliary film 27 and a second adhesive auxiliary film 29 in the structure of the adhesive member 20 of FIG. 2A. The first adhesive auxiliary film 27 may be disposed between the base film 21 and the carrier adhesive film 23, and may improve adhesive strength between the base film 21 and the carrier adhesive film 23. The second adhesive auxiliary film 29 may be disposed between the base film 21 and the device adhesive film 25, and may improve adhesive strength between the base film 21 and the device adhesive film 25. The first adhesive auxiliary film 27 may include the first resin, the first cross-linking agent, and the first filler, that are described above with reference to FIG. 2A. The first adhesive auxiliary film 27 may not include the first release agent and the gas blowing agent, as described above with reference to FIG. 2A. The second adhesive auxiliary film 29 may include the second resin, the second cross-linking agent, and the second filler, as described above with reference to FIG. 2A. The second adhesive auxiliary film 29 may not include the second release agent and the gas blowing agent, as described above with reference to FIG. 2A.

After bonding as illustrated in FIG. 4, processes may be performed as described above with reference to FIGS. 1, 2A to 2H, and 3A to 3E. The first adhesive auxiliary film 27 and the second adhesive auxiliary film 29 may also be cured in the primary curing operation (second operation, S20) of FIG. 1, thus increasing their adhesive strength. However, in the secondary curing operation (fourth operation, S40) of FIG. 1, the first adhesive auxiliary film 27 and the second adhesive auxiliary film 29 may not be further cured, and there may be no change in adhesive strength of the first and second auxiliary films 27, 29. Other matters may be the same as or similar to the above descriptions.

FIG. 5 is a cross-sectional view illustrating a method for manufacturing a semiconductor device according to embodiments of the inventive concept.

Referring to FIG. 5, an adhesive member 20b may not include the base film 21 in the structure of the adhesive member 20 of FIG. 2A. The adhesive member 20b may include the device adhesive film 25 and the carrier adhesive film 23, which are sequentially laminated. In this case, sequentially coating the device adhesive film 25 and the carrier adhesive film 23 on the device wafer 30 may be added before the bonding (first operation, S10) of the carrier substrate 10 onto the device wafer 30 with the adhesive member 20b therebetween. Thereafter, processes may be performed as described above with reference to FIGS. 1, 2A to 2H, and 3A to 3E. Other matters may be the same as or similar to the above descriptions.

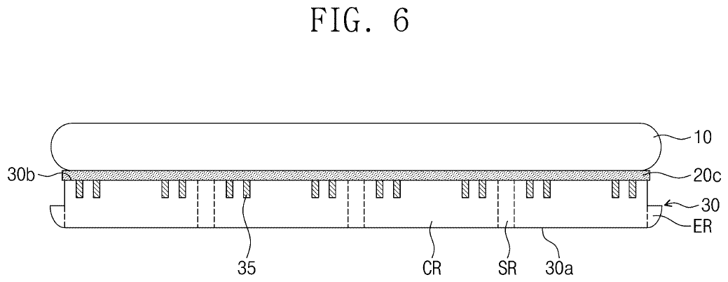

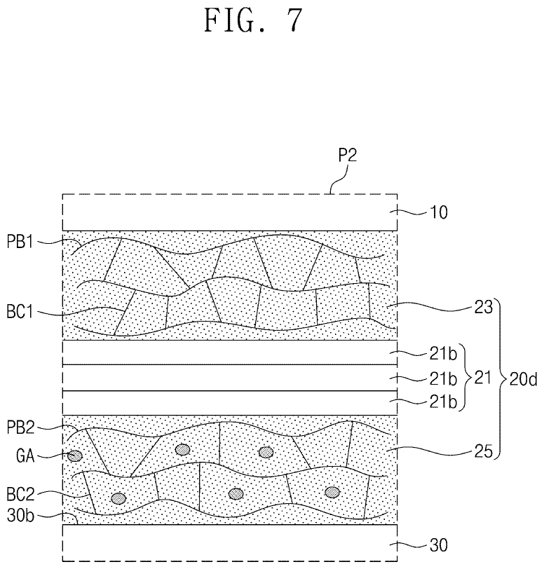

FIG. 6 is a cross-sectional view illustrating a method for manufacturing a semiconductor device according to embodiments of the inventive concept.

Referring to FIG. 6, an adhesive member 20c is formed as a single-layer adhesive film. The adhesive member 20c according to the present example may not include the base film 21 more the carrier adhesive film 23 in the structure of the adhesive member 20 of FIG. 2A. That is, the adhesive member 20c according to the present example may have the same components and composition as the device adhesive film 25 described above with reference to FIG. 2A. That is, the adhesive member 20c may include a resin, the second cross-linking agent, the second filler, the second release agent, and the gas blowing agent. In this case, coating the adhesive member 20c on the device wafer 30 may be added before the bonding (first operation, S10) of the carrier substrate 10 onto the device wafer 30 with the adhesive member 20c therebetween. Thereafter, processes may be performed as described above with reference to FIGS. 1, 2A to 2H, and 3A to 3E. The adhesive member 20c may be disposed between and directly contact the device wafer 30 and the carrier substrate 10. In the present example, the adhesive member 20c is primarily cured in the second operation (S20), and after the back grinding process (third operation, S30) and the pad forming process, the adhesive member 20c is secondarily cured in the fourth operation (S40), and thus has reduced adhesive strength and may be separated from the device wafer 30 without causing a crack (fifth operation, S50). Other matters may be the same as or similar to the above descriptions.

FIG. 7 is an enlarged view of the portion P2 of FIG. 2B according to embodiments of the inventive concept.

Referring to FIG. 7, the base film 21 may be a multi-layer film comprising several films having different Young's modulus, toughness, and elongation. In a specific example, the base film 21 of an adhesive member 20d may include first to third base films 21a, 21b, and 21c sequentially laminated. The first to third base films 21a, 21b, and 21c may have different Young's modulus, toughness, and elongation. Accordingly, the WSS process may be performed more stably. Other configurations and methods may be the same as or similar to the above descriptions of embodiments including a base film 21.

In a method for manufacturing a semiconductor device according to an embodiment of the inventive concept, an adhesive member includes a gas blowing agent, which is decomposed by light of a specific wavelength to form nitrogen gas and radicals. Therefore, when separating the adhesive member and a carrier substrate from a device wafer, adhesive strength of the adhesive member is decreased and pores are formed between the adhesive member and the device wafer by irradiating the adhesive member with light of a specific wavelength, and thus the separation process may be performed smoothly without causing a crack in the device wafer. Therefore, the yield may be improved.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. An adhesive member having a multi-layered film structure, comprising:
a base film having a first surface and a second surface opposite to the first surface;
a carrier adhesive film disposed on the first surface of the base film and configured to contact a carrier substrate; and
a device adhesive film disposed on the second surface of the base film and configured to contact a device wafer,
wherein the device adhesive film comprises a gas blowing agent, and
wherein the carrier adhesive film does not include any gas blowing agent.

2. The adhesive member according to claim 1,
wherein the base film has a thickness of about 10 nm to about 500 μm.

3. The adhesive member according to claim 1,
wherein the carrier adhesive film has a thickness of about 10 nm to about 500 μm.

4. The adhesive member according to claim 1,
wherein the device adhesive film has a thickness of about 10 nm to about 500μ m.

5. The adhesive member according to claim 1,
wherein the base film comprises a polymer film selected from the group consisting of polypropylene, polyethylene, polyvinyl chloride, polyethylene terephthalate, and polyimide.

6. The adhesive member according to claim 1,
wherein the base film is transparent to allow ultraviolet light to be transmitted therethrough.

7. The adhesive member according to claim 1,
wherein the base film is insensitive to ultraviolet light.

8. The adhesive member according to claim 1,
wherein the carrier adhesive film comprises a first resin, a first cross-linking agent, a first filler, and a first release agent,
and wherein the device adhesive film comprises a second resin, a second cross-linking agent, a second filler, and a second release agent.

9. The adhesive member according to claim 8,
wherein the first resin and the second resin are each an acrylate-based polymer having a structure represented by Chemical Formula 1, in which n denotes an arbitrary natural number and R denotes one of hydrogen, an alkyl group, an alkenyl group, and an alkanyl group.

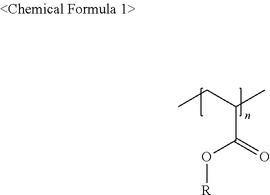

10. The adhesive member according to claim 8,
wherein the first cross-linking agent and the second cross-linking agent are cyanate-based cross-linking agents each having a structure selected from structure I and structure II of Chemical Formula 2, in which R denotes one of hydrogen, an alkyl group, an alkenyl group, and an alkanyl group.

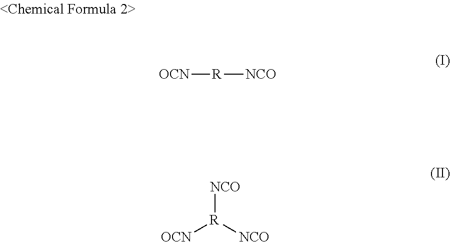

11. The adhesive member according to claim 8,
wherein the first filler and the second filler are the same material selected from the group consisting of silica, alumina, ceria, and titania.

12. The adhesive member according to claim 8,
wherein the first release agent and the second release agent are silicone acrylates having a structure represented by Chemical Formula 3, in which q denotes an arbitrary natural number and R denotes one of an alkyl group, an alkenyl group, and an alkanyl group.

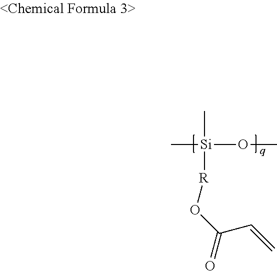

13. The adhesive member according to claim 1,
wherein the carrier adhesive film comprises a first resin in an amount of about 80 to about 99 wt % based on a total weight of the carrier adhesive film.

14. The adhesive member according to claim 13,
wherein the carrier adhesive film further comprises a first cross-linking agent in an amount of about 0.001 to about 1 wt % based on the total weight of the carrier adhesive film.

15. The adhesive member according to claim 13,
wherein the carrier adhesive film further comprises a first filler in an amount of about 0.001 to about 1 wt % based on the total weight of the carrier adhesive film.

16. The adhesive member according to claim 13,
wherein the carrier adhesive film further comprises a first release agent in an amount of about 0.001 to about 1 wt % based on the total weight of the carrier adhesive film.

17. The adhesive member according to claim 1,
wherein the device adhesive film comprises a second resin in an amount of about 80 to about 99 wt % based on a total weight of the device adhesive film.

18. The adhesive member according to claim 17,
wherein the gas blowing agent is present in an amount of about 0.001 to about 1 wt % based on the total weight of the device adhesive film, and
wherein the gas blowing agent comprises diazirine that is decomposable by ultraviolet light having a wavelength of about 350 nm to about 400 nm to form nitrogen gas and a carbene radical.

19. An adhesive member comprising:
a carrier adhesive film configured to bond to a carrier substrate;
a device adhesive film configured to bond to a device wafer; and
a base film disposed between the carrier adhesive film and the device adhesive film,
wherein the device adhesive film is configured to reduce its adhesive strength to the device wafer upon exposure to a specific wavelength of light,
wherein the device adhesive film comprises a gas blowing agent that is decomposable upon exposure to the specific wavelength of light, and
wherein the carrier adhesive film is substantially insensitive to the specific wavelength of light such that its adhesive strength to the carrier substrate remains substantially unchanged upon the exposure.

20. An adhesive member comprising:
a carrier adhesive film contacting a carrier substrate;
a device adhesive film contacting a device wafer; and
a base film disposed between the carrier adhesive film and the device adhesive film,
wherein the base film is transparent to allow ultraviolet light to be transmitted therethrough for processing,
wherein the device adhesive film comprises a gas blowing agent that is decomposable by the transmitted ultraviolet light,
wherein the device adhesive film is configured to be sensitive to the transmitted ultraviolet light to reduce its adhesive strength to the device wafer, and
wherein the carrier adhesive film is configured to be substantially insensitive to the transmitted ultraviolet light such that its adhesive strength to the carrier substrate remains substantially unchanged.
